(19) United States
(12) Patent Application Publication
(10) Pub. No.: US 2017/0271589 A1
(43) Pub. Date: Sep. 21, 2017

(54) RESISTIVE MEMORY ARRAYS WITH A NEGATIVE TEMPERATURE COEFFICIENT OF RESISTANCE MATERIAL

(71) Applicant: Hewlett Packard Enterprise Development LP, Houston, TX (US)

(72) Inventors: Minxian Max Zhang, Mountain View, CA (US); Jianhua Yang, Palo Alto, CA (US); Zhiyong Li, Foster City, CA (US); R. Stanley Williams, Portola Valley, CA (US)

(21) Appl. No.: 15/329,801

(22) PCT Filed: Jan. 26, 2015
(86) PCT No.: PCT/US2015/012909

§ 371 Date: Jan. 27, 2017

(51) Int. Cl. H01L 45/00; H01L 27/24

(52) U.S. Cl. CPC H01L 45/146; H01L 27/2436; H01L 27/2481; H01L 45/06; H01L 45/1233; H01L 45/1633

(57) ABSTRACT

A resistive memory array includes a plurality of resistive memory devices. A sneak path current in the resistive memory array is reduced when a negative temperature coefficient of resistance material is incorporated in series with a negative differential resistance selector that is in series with a memristor switching material at a junction formed at a cross-point between two conductors of one of the plurality of resistive memory devices.

### BACKGROUND

An electronic device may incorporate a selector in order to aid in controlling the electrical properties of the device. In an example device, a selector may be combined with a memristor to form a resistive memory device at each cross-point in a crossbar array of resistive memory devices. Memristors are devices that can be programmed to different resistive states by applying a programming energy, such as a voltage. Large crossbar arrays of memory devices can be used in a variety of applications, including random access memory, non-volatile solid state memory, programmable logic, signal processing control systems, pattern recognition, and other applications.

### BRIEF DESCRIPTION OF THE DRAWINGS

Features and advantages of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 illustrates an example method for reducing sneak path current in a resistive memory array;

FIG. 2 is a semi-schematic, perspective view of an example of a resistive memory array;

FIG. 3 is a flow diagram illustrating an example method for manufacturing a resistive memory device;

FIG. 4 is a semi-schematic, cross-sectional view of one resistive memory device in the resistive memory array, taken along line 4-4 in FIG. 2;

FIG. 5 is a semi-schematic, cross-sectional view of another example resistive memory device; and

FIG. 6 is a semi-schematic, cross-sectional view of yet another example resistive memory device.

### DETAILED DESCRIPTION

Memristors are devices that may be used as components in a wide range of electronic circuits, such as memory devices, switches, radio frequency circuits, and logic circuits and systems. When used as a basis for a memory device, the memristor may be used to store bits of information, e.g., 1 or 0. The resistance of a memristor may be changed by applying an electrical stimulus, such as a voltage or a current, through the memristor. Generally, at least one channel may be formed that is capable of being switched between two states—one in which the channel forms an electrically conductive path (“ON”) and one in which the channel forms a less conductive path (“OFF”).

Several memory devices may be incorporated together into a crossbar array of memory devices. However, using memristors in a crossbar array may lead to read or write error due to sneak path currents passing through the memory devices that are not targeted, such as device(s) on the same row or column as a targeted device. Error may arise when the total operating current through the crossbar array from an applied voltage cannot operate the selected memristor. This may be due to current sneaking from the selected memristor through to untargeted neighboring device(s). Using a transistor coupled in series with each memristor has been proposed to isolate each device and overcome the sneak path current. However, using a transistor with each memristor in a crossbar array may limit array density and increase cost.

Effort has been made to investigate using a nonlinear selector coupled in series with each memristor in order to increase the current-voltage nonlinearity of each memory device of a crossbar array. One type of selector exhibits an insulator-to-metal transition, meaning that the selector transitions from an electrically insulating state to an electrically conducting state similar to a metal. However, it has been found that some selectors allow excessive leakage current in the insulator (“unselected”) state. In other words, some selectors may not be resistive enough, or may leak too much current, even in the unselected state.

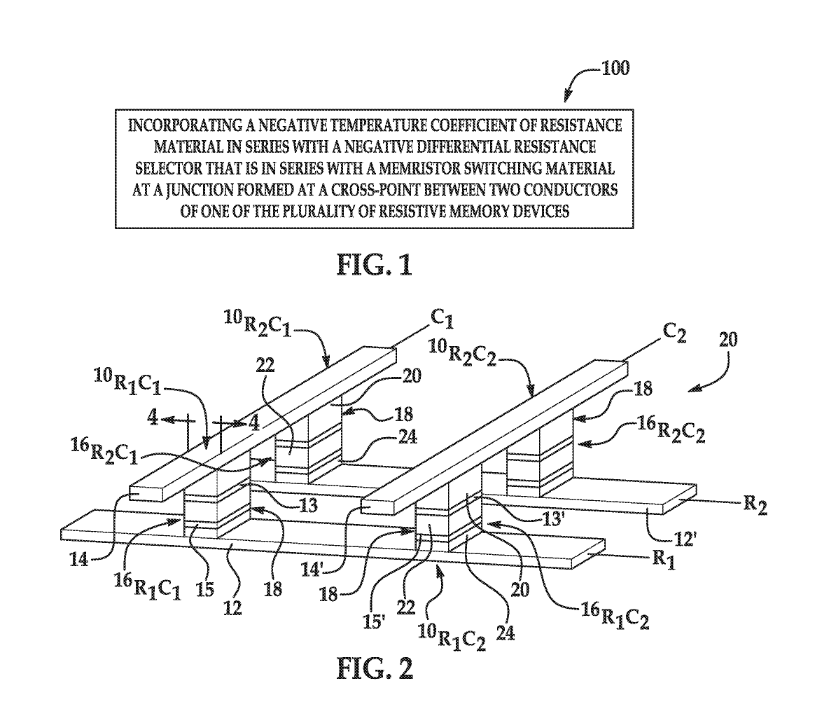

A method for reducing the sneak path/leakage current in the resistive memory, crossbar array (which includes a plurality of resistive memory devices) is disclosed herein. An example of this method 100 is shown in FIG. 1, and includes incorporating a negative temperature coefficient of resistance (NTCR) material in series with a negative differential resistance (NDR) selector, which is in series with a memristor switching material at a junction formed at a cross-point between two conductors (i.e., crossbars, electrodes, etc.) of one of the plurality of resistive memory devices. The term “in series” means that the components are electrically connected along a single path so that the same current flows through all of the components. While the components may be in series, they may or may not be in direct contact with one another, and the order of the components may vary. For example, the memristor switching material may be deposited on an electrode/conductor in contact with the NDR selector, which is deposited on an electrode/conductor in contact with the NTCR material. In this example, the memristor switching material and the NTCR material are in series, but are not in direct contact with one another.

In the example resistive memory devices disclosed herein, the NTCR material is electrically coupled with the NDR selector. The NDR selector undergoes Joule heating when a voltage is applied across, and an electric current is directed through, the resistive memory device. Likewise, when a voltage is not applied, the NDR selector does not undergo Joule heating. In the examples disclosed herein, the NTCR material is tuned so that when the NTCR material is exposed to the heat from the NDR selector, the NTCR material will exhibit a low resistance state. In these instances, both the NDR selector and the NTCR material are conductive, and there is low voltage drop across the NDR selector/NTCR material combination. As such, in these instances, the voltage is primarily, and advantageously, applied to the memristor operation of the targeted resistive memory device. Also in the examples disclosed herein, the NTCR material is tuned so that when the NTCR material is not exposed to the heat from the NDR selector, the NTCR material will exhibit a high resistance state. In these instances, there is a high voltage drop across NTCR material, which reduces the voltage across the memristor of the associated resistive memory device which is not then-currently the targeted resistive memory device of the array. The high resistance state of the NTCR material also reduces leakage current from reaching the unselected memristor.

An example resistive memory array 20 is shown in FIG. 2. As mentioned above, the array 20 includes a plurality of resistive memory devices 10. In the example shown in FIG. 2, the array 20 includes four of the resistive memory devices 10, namely 10_{R1C2}, 1_{R2C2}, 10_{R1C1}, 10_{R2C1}. Generally, the array 20 is an array of switches (i.e., devices, cells, etc.) with two outer sets of conductors forming respective rows R1, R2 and columns C1, C2. The conductors 12, 12′ in the set of parallel bottom conductors cross the conductors 14, 14′ in the set of parallel top conductors at non-zero angles. In many instances, the two outer sets of conductors 12, 12′ and 14, 14′ are perpendicular to each other. However, the two outer sets of conductors 12, 12′ and 14, 14′ may be offset at any non-zero angle. It is to be understood that each of the conductors 12, 12′, 14, 14′ may be a single layer or multiple layers of conductive materials, and may be symmetric or asymmetric,

In the resistive memory array 20, a respective resistive memory device 10_{R1C2}, 10_{R2C2}, 10_{R1C1}, 10_{R2C1} is formed at each pair of crossing conductors 12, 14′, or 12′, 14′, or 12, 14, or 12′, 14. A junction 16_{R1C2}, 16_{R2C2}, 16_{R1C1}, 16_{R2C1} is located at respective cross-points of each pair of crossing conductors 12, 14′, or 12′, 14′, or 12, 14, or 12′, 14.

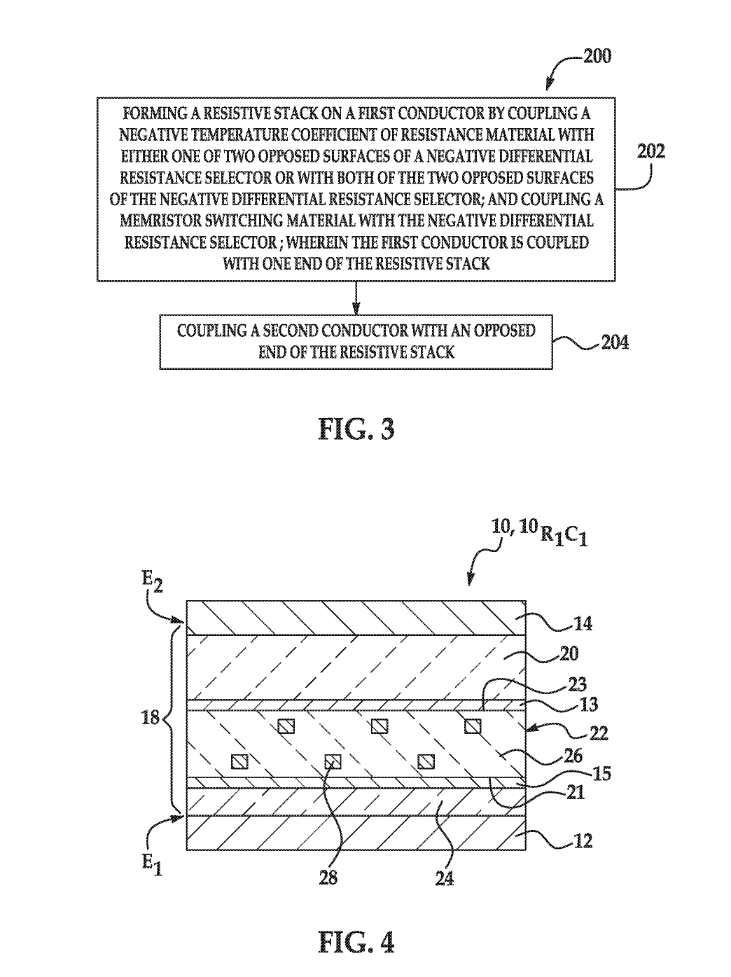

A resistive stack 18 is formed in each junction 16_{R1C2}, 16_{R2C2}, 16_{R1C1} 16_{R2C1}. Each resistive stack 18 includes the memristor switching material 20, the NDR selector 22, and the NTCR material 24. The configuration of the materials 20, 22, 24 within the resistive stack 18 may vary in different examples, and these configurations and the methods for manufacturing the various configurations will be described further herein in reference to FIGS. 3-6.

As shown in FIG. 2, the components 20, 22, 24 of the resistive stack 18 may be separated by additional conductor(s) 13, 13′, 15, 15′. In an example, each component 20, 22, 24 is in direct contact with two opposed conductors. In the example device 10_{R1C1}, the memristor switching material 20 is in direct contact with conductors 14 and 13, the NDR selector 22 is in direct contact with conductors 13 and 15, and the NTCR material 24 is in direct contact with conductors 15 and 12.

While not shown, in another example, an additional conductor 13, 13′ may be positioned between the memristor switching material 20 and either the NDR selector 22 or the NTCR material 24, but the NDR selector 22 and the NTCR material 24 are in direct contact with one another. It is to be understood that the NDR selector 22 and the NTCR material 24 may be placed into direct contact with one another when stability is achieved at the interface of the two components 22, 24.

The conductors 13, 13′, 15, 15′ incorporated between components 20, 22, 24 of the resistive stack 18 are formed as layers within the resistive stack 18, and then the stack may be patterned to a suitable shape of the junction 16_{R1C2}, 16_{R2C2}, 16_{R1C1}, 16_{R2C1}. The conductors 13, 13′, 15, 15′ provide an electrical contact between the components of the resistive stack, The outer conductors 12, 12′ and 14, 14′ positioned at some non-zero angle enable each device 10_{R1C2}, 10_{R2C2}, 10_{R1C1}, 10_{R2C1} in the array 20 to be individually addressed for operation.

It is to be understood that each of the additional conductors 13, 13′, 15, 15′ may be a single layer or multiple layers of conductive materials, and may be symmetric or asymmetric, and may include passivation barrier layer materials.

While the memristor switching material 20 is shown adjacent to the top conductors 14, 14′ in FIG. 2, it is to be understood that the devices 10_{R1C2}, 10_{R2C2}, 10_{R1C1}, 10_{R2C1} may be built with the memristor switching material 20 adjacent to the bottom conductors 12, 12′.

For the array 20, it is to be understood that the memristor switching material 20 at each junction 16_{R1C2}, 16_{R2C2}, 16_{R1C1}, 16_{R2C1} is individually addressable after initial fabrication by virtue of the respective outer conductors 12, 12′ and 14, 14′ in electrical contact with the memristor switching material 20. For example, if the conductor 12 in row R1 and the conductor 14′ in column C2 are addressed with an appropriate voltage and polarity, device 10_{R1C2} is activated and switched to either the ON state or the OFF state, and if the conductor 12′ in row R2 and the conductor 14 in column C1 are addressed with an appropriate voltage and polarity, device 10_{R2C1} is activated and switched to either the ON state or the OFF state. In the array 20, it is to be understood that when one individual device (for example 10_{R1C2}) is addressed/targeted, the combination of the NDR selector 22 and the NTCR material 24 located at each remaining device (for example, 10_{R2C2}, 10_{R1C1}, and 10_{R2C1}) that is not addressed/targeted exhibits a resistance that is sufficiently high to reduce sneak path current at the non-addressed/targeted devices (for example, 10_{R2C2}, 10_{R1C1}, and 10_{R2C1}).

Referring now to FIG. 3, an example of a method 200 for manufacturing examples of the resistive memory device 10 is depicted. It is to be understood that the following discussion of the method 200 shown in FIG. 2 also refers to FIGS. 4 through 6, which illustrate different cross-sectional views of the resistive memory device 10 (device 10_{R1C1} from FIG. 2), 10′, 10″.

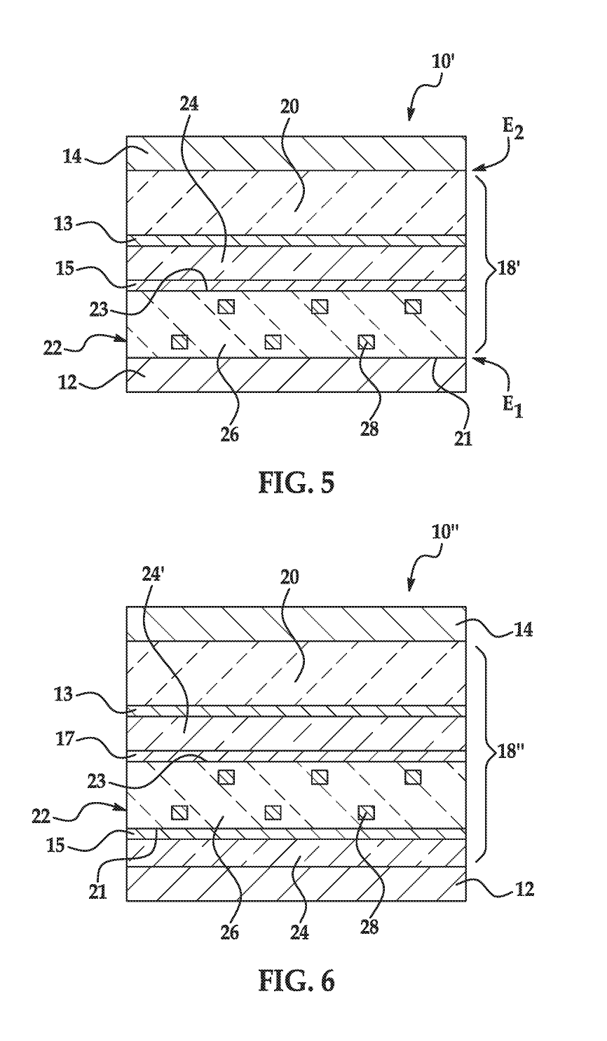

As shown at reference numeral 202 in FIG. 3, the method 200 includes forming the resistive stack 18 on a first conductor. The first conductor (e.g., bottom conductor 12) is coupled with one end E₁ of the resistive stack 18. The resistive stack 18 is formed by coupling the NTCR material 24 with either one of two opposed surfaces 21, 23 of the NDR selector 22 (see FIGS. 4 and 5) or with both of the two opposed surfaces 21, 23 of the NDR selector 22 (see FIG. 6), and coupling the memristor switching material 20 with the NDR selector 22. The method 200 also includes coupling a second conductor (e.g., top conductor 14) with an opposed end E₂ of the resistive stack 18 (reference numeral 204). In the examples disclosed herein, coupling may mean forming an electrically-conducting connection between components. For example, coupling in step 202 of the method 200 may include electrically connecting one or more of the resistive stack 18 components to a conductor (e.g., conductor 13, 13′, 15′, or 15′). A specific example of the coupling in step 202 may include the NTCR material 24 being formed on the first conductor, and then the conductor 15 being formed on the NTCR material 24, and then the NDR selector 22 being formed on the conductor 15, and then the conductor 13 being formed on the NDR selector 22, and then the memristor switching material 20 being formed on the conductor 13.

In an example of the method 200, the first or bottom conductor 12 may be provided or fabricated using any suitable technique, such as lithography (e.g., photolithography, electron beam lithography, imprint lithography, etc.), thermal or e-beam evaporation, sputtering, atomic layer deposition (ALD), or the like. Examples of materials for the bottom electrode 12 include Pt, Ta, Hf, Zr, Al, Co, Ni, Fe, Nb, Mo, W, Cu, Ti, TiN, TaN, Ta₂N, WN₂, NbN, MoN, TiSi₂, TiSi, Ti₅Si₃, TaSi₂, WSi₂, NbSi₂, V₃Si, electrically doped polycrystalline Si, electrically doped polycrystalline Ge, and combinations thereof. Although the conductor 12 is shown with a rectangular cross-section, it is to be understood that the conductor 12 may also have a trapezoidal, a circular, an elliptical, or another more complex cross-section. The conductor 12 may also have many different widths or diameters and aspect ratios or eccentricities. As illustrated in FIG. 2, the bottom conductor 12 may connect the resistive stack 18 to lines of the crossbar array 20.

In one example of coupling one end E₁ of the resistive stack 18 to the bottom conductor 12, the layers of the resistive stack 18 (including any additional conductors 13, 13′, 15, 15′) may be sequentially formed on the bottom conductor 12. In the example of the resistive stack 18 shown in FIG. 4, the NTCR material 24 is formed on the bottom conductor 12, the additional conductor 15 is formed on the NTCR material 24, the NDR selector 22 is formed on the additional conductor 15, the additional conductor 13 is formed on the NDR selector 22, and the memristor switching material 20 is formed on the additional conductor 13. As such, in this example, the NTCR material 24 is in indirect contact with one surface, e.g., surface 21, of the NDR selector 22.

The NTCR material 24 is a metal oxide material. The NTCR material may be a binary metal oxide having the formula MOₓ, or a ternary oxide having the formula M1M2O₃ or M3(M4)₂O₄. In any of the examples disclosed herein, the NTCR material 24 is formed with a controlled or tuned resistance, resistivity, and/or temperature coefficient of resistance. By forming the material with a suitable resistance, resistivity, and/or temperature coefficient of resistance, the NTCR material 24 is capable of increasing its carrier concentration and carrier mobility when exposed to an increasing temperature (e.g., Joule heating of the NDR selector 22). This renders the NTCR material 24 more conductive/less resistive when exposed to higher temperature(s) resulting from device operation (e.g., set or reset mode for the memristor switching material 20), and less conductive/more resistive when exposed to lower temperature(s) (thus protecting the memristor switching material 20 from sneak path current(s) during read mode).

In the formula MO ₓ for the binary oxide, x is the oxygen atom to metal or semi-metal atom ratio, which can range from 0.5 (e.g., for monovalent metals) to 3 (e.g., hexavalent metals). As the oxygen content is increased, the conductivity of the material will decrease, and the temperature coefficient of resistance will also decrease from positive (i.e., the metal behavior) to zero, and then to negative (i.e., semiconductor behavior). When the oxygen content is increased to a certain point (depending upon the metal(s) used), the semiconducting material becomes insulating (i.e., measurement of electrical properties becomes difficult).

In examples of the MOₓ NTCR material 24, M is a metal or a semi-metal selected from the group consisting of Ta, W, Nb, Y, Ti, Zr, Hf, Cr, Mo, Al, and Si, and x is the oxygen atom to metal or semi-metal atom ratio. As such example MOₓ NTCR materials 24 include TaOₓ, WOₓ, NbOₓ, YOₓ, TiOₓ, ZrOₓ, HfOₓ, CrOₓ, MoOₓ, AlOₓ, and SiOₓ.

As mentioned above, ternary oxides having the formula M1M2O₃ or M3(M4)₂O₄ may exhibit NTCR.

M1M2O₃ has a perovskite structure, with two sublattices for cations (M1 and M2) and one sublattice for an anion (O). In examples of the M1M2O₃ NTCR material 24, M1 is a relatively large divalent cation selected from the group consisting of Ba, Ca, Pb, and Sc, and M2 is a relatively small tetravalent cation selected from the group consisting of Ti, Bi, Zr, and Nb. Some specific examples of the M1M2O₃ NTCR material 24 include BaBiO₃, BaTiO3, BaNbO₃, BaZrO₃, and CaTiO₃. M1M2O₃ can also be doped to achieve suitable semiconductor properties. For example, when BaBiO₃ (with M1=Ba and M2=Bi) is properly doped with La, e.g., at 3% of La on Bi sublattice, or with formula Ba(Bi_{0.97}La_{0.03})O₃, the conductivity can be increased approximately by a factor of 10, while the NTCR remains approximately unchanged.

Another ternary oxide is M3(M4)₂O₄, which has a spinel structure, where M3 is a divalent cation, M4 is a trivalent cation, and 0 is a divalent anion. Examples of M3 include Ni and Mg, examples of M4 include Al and Mn. A specific example of M3(M4)₂O₄ includes undoped NiMn₂O₄, with M3=Ni and M4=Mn. The NTCR of undoped NiMn₂O₄ is −0.037/K. NiMn₂O₄ can also be doped with Co or Co and Cu. Depending upon the level of Co or Co and Cu doping, the resistivity can be varied from 10 Ω·cm to 1,000 ∩·cm, and the doped NiMn₂O₄ remains an NTCR material. In other examples, the ratio of M4 (e.g., Mn) to M3 (e.g., Ni) may be varied. By increasing the Mn to Ni ratio, the resistivity can be increased from 5,600 Ω·cm up to 100,000 ∩·cm, and the NTCR can be changed from −0.037/K to −0.051/K.

As mentioned above, the NTCR material 24 is formed with a controlled or tuned resistance, resistivity, and/or temperature coefficient of resistance (TCR). The resistance, resistivity, and/or TCR may be controlled/tuned by controlling the composition of the NTCR material 24 and/or by controlling the geometry (in particular, the unit area and thickness) of the NTCR material 24.

In controlling the resistivity and NTCR of a binary oxide MOₓ, the oxygen content of the NTCR material 24 may be adjusted during or after the formation of the NTCR material 24. In an example, the NTCR material 24 may be exposed to oxidation as the NTCR material 24 is being deposited or after the NTCR material 24 is deposited. In an example, the NTCR material 24 is sputtered from elemental metal or semi-metal target(s). Sputtering may be accomplished in the presence of an inert gas (e.g., Ar). An oxygen gas (O₂) may also be introduced during sputtering in order to oxidize the sputtered metal atoms. The oxygen concentration of the resulting material NTCR 24 may be tuned by controlling the O₂/Ar flow ratio during the sputter deposition of the metal or semi-metal materials, and/or by controlling the exposure time to the oxygen gas, and/or by controlling the temperature at which the metal is exposed to the oxygen gas.

An increased O₂ flow rate will increase the oxygen concentration in the binary oxide MOₓ NTCR material 24. In an example, the inert gas flow rate ranges from about 16 standard cubic centimeters per minute (sccm) to about 20 sccm, and the O₂ flow rate ranges from 0 sccm to about 8 sccm. The O₂/Ar flow ratio may range from 0% to about 50%. As examples, the oxygen concentration (atomic percent) of TaOₓ may be increased to about 75% with an O₂/Ar ratio ranging from about 10% to about 25%; the oxygen concentration (atomic percent) of WO may be increased to anywhere from about 65% to about 80% with an O₂/Ar ratio ranging from about 20% to about 50%; and the oxygen concentration (atomic percent) of NbO may be increased to anywhere from about 70% to about 75% with an O₂/Ar ratio ranging from about 10% to about 25%.

In another example, a material may be sputtered in an inert gas, and then a post deposition treatment may be performed. In this post deposition treatment, the deposited metal(s) may be exposed to an oxidizing or reducing environment to adjust the oxygen content in the deposited metal(s) or semi-metal(s) to form the binary oxide MOₓ NTCR material 24.

An increased O₂ exposure time will also increase the oxygen concentration in the binary oxide MOₓ NTCR material 24. Additionally, the reaction rate of oxygen with some metals or semi-metals may increase with an increase in temperature. As such, the temperature may be varied to adjust the oxygen content in the deposited metal/semi-metal for binary oxides, as well as in ternary oxides, which in turn results in changes in the NTCR and resistivity values. For example, NTCR and resistivity of a spinel NiMn₂O₄ can change from −0.0361/K to −0.0404/K, and from 3,500 Ω·cm to 21,000 ∩≠cm, respectively, after annealing in RTA (rapid thermal annealing) in air for 1 minute at a temperature ranging from 630° C. to 930° C.

As the oxygen concentration increases in the NTCR material 24, the higher the resistivity of the NTCR material 24, and the more negative the temperature coefficient of resistance of the NTCR material 24. When a semiconductor becomes more insulating, its resistivity depends upon the carrier concentration and mobility. Both carrier concentration and mobility increase with temperature, and this corresponds with a more negative temperature coefficient of resistance. A higher resistivity also leads to a higher resistance. Table 1 illustrates the temperature coefficient of resistance (TCR) and the resistivity for various examples of MOₓ (i.e., TaOₓ, WOₓ, and NbOₓ) with an increasing oxygen content (which is proportional to oxygen 2p valence band intensity expressed by % area).

TABLE 1

| | TaOₓ | | | |
|---|---|---|---|---|
| O 2p Valance Band | 20 | 60 | 80 | 90 |
| Intensity (% area) | | | | |
| TCR (K⁻¹) | 0 | ~−0.0001 | ~−0.0005 | ~−0.0025 |
| Resistivity, ρ* | ~300 | ~1000 | ~1*10⁴ | ~3*10⁵ |
| (μΩ · cm) | | | | |

| | WOₓ | | |
|---|---|---|---|
| O 2p Valance Band | 20 | 60 | 80 |
| Intensity (% area) | | | |
| TCR (K⁻¹) | ~−0.0001 | ~−0.0014 | ~−0.0025 |
| Resistivity, ρ* | ~90 | ~900 | ~2000 |
| (μΩ · cm) | | | |

| | NbOₓ | | | |
|---|---|---|---|---|
| O 2p Valance Band | 20 | 60 | 80 | 85 |
| Intensity (% area) | | | | |
| TCR (K⁻¹) | 0.001 | ~−0.003 | ~−0.011 | ~−0.025 |
| Resistivity, ρ* | ~20 | ~110 | ~10⁴ | ~3*10⁴ |
| (μΩ · cm) | | | | |

For each of the MOₓ materials, as the oxygen concentration increases (and the O 2p band intensity increases), the resistivity increases and the TCR becomes more negative (indicating the onset of semiconducting conduction).

The resistance of the NTCR material 24 that is not exposed to Joule heating depends, at least in part, on the resistivity (ρ) of the NTCR material 24, the length or thickness (L) of the NTCR material 24, and the cross sectional area (A) of the NTCR material 24. For example, the resistance of the NTCR material 24 when not exposed to Joule heating may be calculated using equation (I):

$$R° = ρ ( \frac{L}{A} )$$

As evidenced by Table 1, the resistivity (p) is a function of oxygen concentration in the NTCR material 24, as well as a function of temperature. When the NTCR material 24 is not being exposed to joule heating (device is unselected), the temperature can be assumed to be constant, As such, the resistivity (and thus the resistance (R°)) may be adjusted by altering the oxygen concentration of the NTCR material 24. Also as shown in equation I, the length and/or cross sectional area may be altered in order to tune the resistance of the NTCR material 24 that is not exposed to Joule heating.

Equation I may also be used to calculate the resistance of the NTCR material 24 when exposed to Joule heating, except in this instance, the resistivity is a function of the temperature when exposed to Joule heating (i.e., temperature is not assumed to be constant). In another example, the resistance (R_{T}) of the NTCR material 24 that is exposed to Joule heating relative to the resistance (R°) of the NTCR material 24 that is not exposed to Joule heating, may be calculated using equation (II):

R_{T}=R°(1++ΔT)

where α is the TCR of the NTCR material 24, and ΔT is the change in temperature of the material 24 as a result of the Joule heating. Since the TCR of the NTCR material 24 disclosed herein is negative, the resistance (R_{T}) of the NTCR material 24 that is exposed to Joule heating is less than the resistance (R°) of the NTCR material 24 that is not exposed to Joule heating.

In an example, the resistance change ratio, R°/R_{T}, of the NTCR material 24 may range from about 2 to about 10, depending on the a value and the AT value. The resistance change ratio may be adjusted by adjusting the resistance of the NTCR material 24 which is not exposed to Joule heating (R° in equation (I)), which may be adjusted by varying the resistivity (e.g., through oxygen concentration), the geometry (length and/or the cross-sectional area of the NTCR material 24), the TCR (e.g., through oxygen concentration), and/or the ΔT (the temperature difference between being exposed to Joule heating and not being exposed to Joule heating). The resistance change ratio may also be expressed as R_{T}/R°, and this ratio may range from about 0.1 to less than 1.

The following table (Table 2) provides examples of various metal-oxygen binary NTCR materials 24 and the various characteristics that may be tuned. In this example, the NTCR has a thickness (L) of 5 nm, a diameter of 25 nm, a disc shape cross-sectional area of −491 nm², a TCR of −0.0025 K⁻¹, and a change in temperature (ΔT) of +100, +200, and +300° C., respectively, as a result of Joule heating of an NbO₂ NSR selector 22.

TABLE 2

| NTCR | | | | | | R_{T}/R° | R_{T}/R° | R_{T}/R° |
|---|---|---|---|---|---|---|---|---|
| Material | | TCR* | ρ* | ρ | | ΔT = | ΔT = | ΔT = |
| System | Example | (1/K) | (μΩ · cm) | (Ω · nm) | R° (Ω) | 100° C. | 200° C. | 300° C. |
| M-O | Ta—O | −0.0025 | 3 * 10⁵ | 3E6 | 30,000 | 0.75 | 0.50 | 0.25 |
| | | | (i.e., 3E5) | | | | | |
| M-O | W—O | −0.0025 | 2E3 | 2E4 | 200 | 0.75 | 0.50 | 0.25 |
| M-O | Nb—O | −0.0025 | 3E2 | 3E3 | 30 | 0.75 | 0.50 | 0.25 |

*I. Goldfard, et al., “Electronic Structure and transport measurements of amorphous transition-metal oxides: observation of Fermi glass behavior” Appl Phys A (published on line 9 Mar. 2012).

As illustrated in Table 2, the three different NTCR materials 24 exhibited resistances ranging from a few ohms to tens of kilo-ohms, and a resistance decrease of up to 75% with ΔT=300° C. due to Joule heating. These examples illustrate that several characteristics of the NTCR material 24 may be varied in order to tune the high and low resistance states of the material 24, so that the material 24 desirably responds when exposed to and not exposed to Joule heating.

Additionally, NTCR materials 24 with more negative TCR values may be used. In Table 3 below, more negative NTCR data from the Nb—O system is shown, as well as NTCR data from BaBiO₃ and NiMn₂O₄ systems.

TABLE 3

| NTCR | | | | | | R_{T}/R° | R_{T}/R° | R_{T}/R° |
|---|---|---|---|---|---|---|---|---|
| Material | | TCR | | ρ | | ΔT = | ΔT = | ΔT = |
| System | Example | (1/K) | ρ (Ω · cm) | (Ω · nm) | R° (Ω) | 10° C. | 20° C. | 30° C. |
| M-O | Nb—O | −0.025* | 3 * 10⁻² | 3E5 | 3,000 | 0.75 | 0.50 | 0.25 |
| | | | (i.e., 3E−2*) | | | | | |
| M1M2O₃ | BaBiO₃ | −0.029** | ~4E3** | ~4E10 | 4E8 | 0.71 | 0.42 | 0.13 |
| M3(M4)₂O₄ | NiMn₂O₄ | −0.037*** | ~6E3*** | ~6E10 | 6E8 | 0.63 | 0.26 | — |

*I. Goldfard, et al., “Electronic Structure and transport measurements of amorphous transition-metal oxides: observation of Fermi glass behavior” Appl Phys A (published on line 09 March 2012).
**Y. Luo, et al., “NTCR Behavior of La-doped BaBiO₃ Ceramics” Advances in Materials Science and Engineering, Vol. 2009, Art. ID 383842, 4 pages.
***H. Schulze, et al. “Synthesis, Phase Characterization, and Properties of Chemical Solution-Deposited Nickel Manganite Thermistor Thin Films” J. Am. Ceram. Soc. 92 [3] 738-744 (2009).

As illustrated in Table 3, a significant decrease in resistance from the NTCR material 24 may be achieved when ΔT is in the range of tens of degrees centigrade, compared with Table 2 where ΔT is in the range of hundreds of degrees centigrade, For example, with ΔT=20° C., the ratio of the NTCR resistance (R_{T}) with Joule healing to the NTCR resistance (In without Joule heating is estimated to be 50%, 42%, and 26%, respectively, from Nb—O, BaBiO₃ and NiMn₂O₄ NTCR materials.

It is to be understood that the NTCR materials 24 in Table 2 and Table 3 are for illustration purposes, and that the NTCR material 24 may be selected from a wide range of suitable NTCR materials. For example, the resistivity of BaBiO₃ can be decreased by about one order of magnitude with 3% La doped on the Bi sublattice. In another example, the resistivity of NiMn₂O₄ can be decreased from 5600 Ω·cm to 10 Ω·cm by doping with Co and Cu.

The NTCR material 24 that is formed may have any suitable geometry, the length and/or cross sectional area of which may be tuned to change the resistance of the NTCR material 24. In an example, the thickness of the NTCR material 24 may range from about 2 nm to about 100 nm.

In the example device 10 shown in FIG. 4, the resistive stack 18 includes the NDR selector 22 positioned in indirect contact with the NTCR material 24 with the additional conductor 15 positioned therebetween, The NDR selector 22 may be a multiphase selector, which may have a plurality of phases of various materials, including materials that exhibit insulator-to-metal transition in certain voltage ranges. During insulator-to-metal transitions, as the voltage across the NDR selector 22 decreases, the current increases (and by Ohm's law, the differential resistance of the NDR selector 22 is negative). The NDR selector 22 may switch from behaving as an insulator to behaving as a conducting metal when a voltage greater than a threshold voltage is applied. Correspondingly, the NDR selector 22 may behave as an insulator when a voltage less than a threshold voltage is applied or if no voltage is applied. Accordingly, due to the abrupt change in conductivity at a threshold voltage, the NDR selector 22 may exhibit nonlinear current-voltage behavior in certain voltage ranges. In other words, when a voltage greater than a threshold voltage is applied across the NDR selector 22, the current passing through NDR selector 22 changes by an amount greater than the proportional increase in voltage. In some implementations, the threshold voltage for NDR selector 22 may be within a voltage range of interest, where the voltage range used for reading is below the threshold voltage and the voltage range for writing is above the threshold voltage of the resistive memory devices 10 (e.g., 10_{R1C2}, 10_{R2C2}, 10_{R1C1}, 10_{R2C1}) in the array 20.

In an example, the NDR selector 22 may have matrix 26, which contains a transition metal oxide in a first, relatively insulating phase. The matrix 26 may be the principal structure of NDR selector 22, and in some examples, the matrix 26 may make up the entirety of the NDR selector 22. In some other examples, matrix 26 may make up a portion of NDR selector 22. The NDR selector 22 may be generally insulating due to the predominant first phase of the transition metal oxide in matrix 26. The metal that forms the metal oxide may be selected from a number of suitable candidates, including niobium (Nb), tantalum (Ta), and vanadium (V). In an example, the first phase in matrix 26 may be niobium pentoxide (Nb₂O₅).

The NDR selector 22 may be nonhomogeneous and may also have second phase 28 of the transition metal oxide dispersed in matrix 26. The second phase 28 may be relatively conducting compared to the first phase of matrix 26. In some examples, second phase 28 may be less oxygen-rich than the first phase. In a particular example, second phase 28 may be niobium dioxide (NbO₂), titanium(III) oxide (Ti₂O₃), or vanadium dioxide (VO₂). In some examples, second phase 28 may be formed within the matrix 26 out of the first phase. In other words, NDR selector 22 may be formed, for example, by first forming a matrix 26 made of Nb₂O₅. A chemical reaction may then be promoted where NbO₂ is formed out of the Nb₂O₅ matrix. The chemical reaction may be promoted by an electrical operation, which forms an NbO₂ channel in the Nb₂O₅ matrix. From such reactions, the second phase 28 may tend to form in clusters of varying sizes, including clusters of single molecules and clusters of several nanometers across or larger. In some examples, the average size of the clusters of second phase 28 within matrix 26 may be two nanometers or less.

The presence of second phase 28 within matrix 26 may be the cause of the insulator-to-metal transition ability of NDR selector 22. Because the second phase 28 is more conducting than the first phase of the transition metal oxide, a current channel may be formed in matrix 26 at a lower voltage than would be normally required through matrix 26 without second phase 28. The second phase 28 may be distributed throughout matrix 26 to allow current channels to form through the thickness of the NDR selector 22 and create a continuous electrical path through the NDR selector 22.

In an example, the NDR selector 22 may be formed via any suitable deposition technique, An example includes sputter deposition of the metal target under a controlled oxygen/argon atmosphere. As mentioned above, the NDR selector 22 may be deposited with matrix 26 having only the first phase of the transition metal oxide, and then the second phase 28 may be formed out of the first phase. For example, Nb atoms may be scattered into matrix 26, where the atoms may interact with the first phase of matrix 26. For example, the introduced Nb atoms may react with Nb₂O₅ to form NbO₂ as second phase 28.

Also in the example device 10 shown in FIG. 4, the resistive stack 18 includes the memristor switching material 20 positioned in indirect contact with the NDR selector 22 with the additional conductor 13 positioned therebetween, The memristor switching material 20 has a resistance that changes with an applied voltage across or through the memristor switching material 20. Furthermore, the memristor switching material 20 may “memorize” its last resistance without applying any electric voltage (i.e., non-volatile), In this manner, the resistive memory device 10 having memristor switching material 20 may be set to at least two states.

In the examples disclosed herein, the memristor switching material 20 may be based on a variety of materials. The memristor switching material 20 may be oxide-based, meaning that at least a portion of the memristor switching material 20 is formed from an oxide-containing material. The memristor switching material 20 may also be nitride-based, meaning that at least a portion of the memristor switching material 20 is formed from a nitride-containing composition. Furthermore, the memristor switching material 20 may be oxy-nitride based, meaning that a portion of the memristor switching material 20 is formed from an oxide-containing material and that a portion of the memristor switching material 20 is formed from a nitride-containing material. In some examples, the memristor switching material 20 may be formed based on tantalum oxide (TaOₓ) or hafnium oxide (HfOₓ) compositions. Other example materials for the memristor switching material 20 may include titanium oxide, yttrium oxide, niobium oxide, zirconium oxide, aluminum oxide, calcium oxide, magnesium oxide, dysprosium oxide, lanthanum oxide, silicon dioxide, or other like oxides. Further examples include nitrides, such as aluminum nitride, gallium nitride, tantalum nitride, and silicon nitride.

In addition, it is to be understood that other functioning memristors may be employed in the examples disclosed herein. For example, the memristor portion of the device 10 may have multiple layers that include electrodes/conductors and dielectric materials.

When forming the resistive stack 18, it is to be understood that the conductors 13, 13′, 15, 15′ may be pre-formed electrodes that are placed in the suitable position, or may be electrode material that is deposited upon a suitable component.

In this example device 10, the other end E₂ of the resistive stack 18 may be coupled to the second/top conductor 14. Prior to coupling the top electrode 14 the resistive stack 18 (including any conductors 13, 13′, 15, 15′ therein) to be positioned at the junction 16 may be patterned to the size of the junction 16. It is to be understood that after initial formation, the stack 18 may extend across conductor 12, and thus may extend beyond the junction 16 to be formed between addressing conductors 12, 12′ and 14, 14′. In these instances, the entire stack 18 may be patterned to the shape of the junction 16. Patterning may be accomplished using masking and etching, or some other suitable selective removal technique. A single etchant or multiple etchants may be used that is/are capable of removing portions of each layer of the stack that is present outside of the junction 16.

In an example, after the stack 18 is etched and positioned at the junction, junction (i.e., bit) isolation may be accomplished. Junction isolation may be accomplished by depositing an insulating dielectric material on exposed surfaces of the conductor 12, 12′ (or on the surface of an underlying substrate (not shown) so that the insulating dielectric material(s) partially or completely surround the stack 18.

Suitable deposition techniques for the insulating dielectric material(s) include physical and chemical techniques, including evaporation from a heated source, such as a filament or a Knudsen cell, electron beam (i.e., e-beam) evaporation from a crucible, sputtering from a target, other forms of evaporation, chemical vapor deposition (CVD), physical vapor deposition (PVD), molecular beam deposition, atomic layer deposition (ALD), pulse laser deposition, or various other forms of chemical vapor or beam growth from reactive precursors. Appropriate deposition or growth conditions, such as speed and temperature, may be selected to achieve the desirable chemical composition and local atomic structure desired for the insulating dielectric material(s).

Examples of suitable materials for the insulating dielectric material include silicon dioxide (SiO₂), silicon nitride (Si₃N₄), spin-on-glass, or aluminum oxide (Al₂O₃).

In this example, the other end E₂ of the resistive stack 18 may be coupled to the second/top conductor 14. In this particular example, the memristor switching material 20 is in direct contact with the second/top conductor 14. The top conductor 14 may be formed of any of the material set forth herein for the bottom conductor 12. The top conductor 14 is positioned at some non-zero angle with respect to the bottom conductor 12. This non-zero angle positioning prevents shorting of the resulting device(s)/cell(s) 10, for example, when multiple devices/cells 10 are formed on a single conductor 14 in the crossbar array configuration.

In the device 10′ shown in FIG. 5, the resistive stack 18′ is formed on the bottom conductor 12, but in this example, the NDR selector 22 is formed directly on the bottom conductor 12, the NTCR material 24 is formed on the conductor 15 which is on the opposed surface 23 of the NDR selector 22, and the memristor switching material is formed on conductor 13, which is on the NTCR material 24. In this example device 10′, the other end E₂ of the resistive stack 18 may be coupled to the second/top conductor 14. In this particular example, the memristor switching material 20 is in direct contact with the second/top conductor 14.

In the device 10″ shown in FIG. 6, the resistive stack 18″ includes two NTCR material layers/films 24, 24′ on conductors 15, 17 positioned on opposed surfaces 21 and 23 of the NDR selector 22. In an example, the NTCR materials 24, 24′ can be the same, or at least exhibit similar high and low resistance states when not exposed and when exposed, respectively, to Joule heating. In an example, the combined resistivity change of the two NTCR materials 24, 24′ may be doubled compared to the resistivity change of a single NTCR material 24.

As shown in FIG. 6, the NTCR material 24 is formed directly on the bottom conductor 12, and the NDR selector 22 is formed on conductor 15 positioned on the NTCR material 24. As such, the NTCR material 24 is in indirect contact with the surface 21 of the NDR selector 22. A second NTCR material 24′ is formed on conductor 17, which is in contact with the opposed surface 23 of the NDR selector 22. In this example, the extra NTCR material 24′ provides an additional layer to protect the device 10″ from sneak path currents. The memristor switching material 20 is formed on yet another conductor 13, which is in contact with an opposed surface of the second NTCR material 24′. In this example device 10″, the other end E₂ of the resistive stack 18″ may be coupled to the second/top conductor 14 via the memristor switching material 20.

In any of the examples disclosed herein, electrical connectors may contact the conductors 12, 12′, 14, 14′ in order to electrically address the conductors in a particular manner.

While not shown in the examples disclosed herein, it is to be understood that the devices 10, 10′, 10″ may be supported on an insulating layer. The insulating layer may be used alone, or in combination with another substrate. An example of a suitable insulating layer is silicon dioxide (SiO₂) and an example of a suitable substrate is a silicon (Si) wafer. As an example, the devices 10, 10′, 10″ may be fabricated directly on the insulating layer supported by the substrate. For example, the bottom conductor(s) 12, 12′ may be formed and patterned on the insulating layer, and then the other device components may be fabricated thereon in accordance with any of the methods described herein.

When an array of the devices 10, 10′, 10″ is in use, a particular bottom and top conductor 12, 12′ and 14, 14′ may be selected and electrically addressed so that at least a threshold voltage is applied across the targeted device 10, 10′, 10″. In the targeted device 10, 10′, 10′, the applied bias is sufficient for the NDR selector 22 to experience IMT (insulator-metal transition) from Joule heating, thereby resulting in a temperature increase in the targeted device 10, 10′, 10″. This temperature increase causes the NTCR material 24 or 24, 24′ to transition to its low resistance state, so that there is a reduced voltage drop across the NTCR material 24 or 24, 24′ and the applied voltage can facilitate the memristor switching material 20 operation (e.g., set or reset).

When a device 10, 10′, 10″ in the array 20 is targeted, the non-targeted, neighboring devices (i.e., those device(s) 10, 10′, 10″ positioned along the addressed bottom or top conductor 12, 12′ or 14, 14′ but spaced apart from the targeted device 10, 10′, 10″) may be under some bias. However, this bias is insufficient to render a transition in the resistance state of the NDR selector 22 and thus the NDR selector 22 does not experience Joule heating. In these instances, the NTCR material 24 or 24, 24′ of the non-targeted, neighboring devices is in a high resistance state, and prevents or reduces sneak path currents from passing through the non-targeted, neighboring devices.

It is to be understood that the components of the examples disclosed herein may be positioned in a number of different orientations, and any directional terminology used in relation to the orientation of the components is used for purposes of illustration and is in no way limiting, unless specified otherwise. Directional terminology includes words such as “top,” “bottom,” “horizontal,” “vertical,” etc. As an example, any of the devices may be oriented with the conductors 14, 14′ as the bottom conductor, and the conductor 12, 12′ as the top conductors.

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

It is to be understood that the ranges provided herein include the stated range and any value or sub-range within the stated range. For example, a range of from about 2 nm to about 100 nm should be interpreted to include not only the explicitly recited limits of from about 2 nm to about 100 nm, but also to include individual values, such as 8.3 nm, 32.25 nm, 85 nm, etc., and sub-ranges, such as from about 10 nm to about 90 nm, from about 25 nm to about 75 nm, etc.

Furthermore, when “about” or “substantially” is utilized to describe a value, this is meant to encompass minor variations (up to +/−10%) from the stated value.

In describing and claiming the examples disclosed herein, the singular forms “a”, “an”, and “the” include plural referents unless the context clearly dictates otherwise.

While several examples have been described in detail, it will be apparent to those skilled in the art that the disclosed examples may be modified. Therefore, the foregoing description is to be considered non-limiting.

What is claimed is:

1. A resistive memory array, comprising:
a bottom conductor;
a first top conductor;
a second top conductor, wherein each of the first and second top conductors are electrically isolated from one another and cross the bottom conductor at respective non-zero angles;
a first junction formed at a first cross-point of the bottom conductor and the first top conductor;
a second junction formed at a second cross-point of he bottom conductor and the second top conductor; and
a resistive stack positioned at each of the first and second junctions, the resistive stack including:
a memristor switching material;
a negative differential resistance selector in series with the memristor switching material, wherein the negative differential resistance selector has two opposed surfaces; and
a negative temperature coefficient of resistance material positioned on either one of the two opposed surfaces or on both of the two opposed surfaces.

2. The resistive memory array as defined in claim 1 wherein the negative temperature coefficient of resistance material is a binary metal oxide (MOₓ), wherein M is a metal or a semi-metal selected from the group consisting of Ta, W, Nb, Y, Ti, Zr, Hf, Cr, Mo, Al, and Si, and x is a ratio of an oxygen atom to a metal or semi-metal atom in the binary metal oxide.

3. The resistive memory array as defined in claim 1 wherein the negative temperature coefficient of resistance material has a perovskite structure, M1M2O₃, and wherein M1 is selected from the group consisting of Ba, Ca, Pb, and Sc, and M2 is selected from the group consisting of Ti, Zr, and Nb.

4. The resistive memory array as defined in claim 1 wherein the negative temperature coefficient of resistance material has a spinel structure, M3(M4)₂O₄, and wherein M3 is selected from the group consisting of Ni and Mg, and M4 is selected from the group consisting of Al and Mn.

5. The resistive memory array as defined in claim 1 wherein a resistance of the negative temperature coefficient decreases in response to Joule heating of the negative differential resistance selector.

6. The resistive memory array as defined in claim 1 wherein a thickness of the negative temperature coefficient of resistance material ranges from about 2 nm to about 100 nm.

7. The resistive memory array as defined in claim 1 wherein a resistance change ratio, R°/R_{T}, of the negative temperature coefficient of resistance material ranges from 2 to 10, wherein R° is a resistance of the negative temperature coefficient of resistance material when the negative differential resistance selector is not exposed to Joule heating and wherein R_{T} is a resistance of the negative temperature coefficient of resistance material when the negative differential resistance selector is exposed to Joule heating.

8. The resistive memory array as defined in claim 1 wherein the negative differential resistance material includes NbO₂, Ti₂O₃, or VO₂.

9. A method of manufacturing a resistive memory device, the method comprising:
forming a resistive stack on a first conductor by:
coupling a negative temperature coefficient of resistance material with either one of two opposed surfaces of a negative differential resistance selector or with both of the two opposed surfaces of the negative differential resistance selector; and
coupling a memristor switching material with the negative differential resistance selector;
wherein the first conductor is coupled with one end of the resistive stack; and
coupling a second conductor with an opposed end of the resistive stack.

10. The method as defined in claim 9, further comprising adjusting an oxygen content of the negative temperature coefficient of resistance material to tune any of a temperature coefficient of resistance of the negative temperature coefficient of resistance material or a resistivity of the negative temperature coefficient of resistance material,

11. The method as defined in claim 10 wherein adjusting the oxygen content of the negative temperature coefficient of resistance material is accomplished by exposing the negative temperature coefficient of resistance material to oxidation as it is being coupled or after it is coupled.

12. The method as defined in claim 9, further comprising:
selecting a geometry of the negative temperature coefficient of resistance material to tune a resistance of a high resistance state of the negative temperature coefficient of resistance material; and
selecting a temperature coefficient of resistance of the negative temperature coefficient of resistance material to tune a resistance of a low resistance state of the negative temperature coefficient of resistance material.

13. The method as defined in claim 9 wherein:
the coupling of the negative temperature coefficient of resistance material includes depositing the negative temperature coefficient of resistance material on one of the two opposed surfaces of the negative differential resistance selector; and
the coupling of the memristor switching material with the negative differential resistance selector includes depositing the memristor switching material on i) the negative temperature coefficient of resistance material, or ii) an other of the two opposed surfaces of the negative differential resistance selector.

14. A method for reducing a sneak path current in a resistive memory array including a plurality of resistive memory devices, the method comprising:
incorporating a negative temperature coefficient of resistance material in series with a negative differential resistance selector that is in series with a memristor switching material at a junction formed at a cross-point between two conductors of one of the plurality of resistive memory devices.

15. The method as defined in claim 14 wherein the negative temperature coefficient of resistance material is incorporated i) between the negative differential resistance selector and the memristor switching material, or ii) on a surface of the negative differential resistance selector that is opposed to an other surface of the negative differential resistance selector that is in contact with the memristor switching material, or iii) on both of two opposed surfaces of the negative differential resistance selector.
